(19) United States
(12) Patent Application Publication
(10) Pub. No.: US 2026/0362821 A1
(43) Pub. Date: Nov. 12, 2026

(54) SOLAR BATTERY CELL AND SOLAR BATTERY MODULE

(71) Applicant: KENEKA CORPORATION, Osaka (JP)

(72) Inventor: Toru SAWADA, Osaka-shi, Osaka (JP)

(73) Assignee: KENEKA CORPORATION, Osaka (JP)

(21) Appl. No.: 19/126,983

(22) PCT Filed: Oct. 31, 2023
(86) PCT No.: PCT/JP2023/039204

§ 371 Date: May 2, 2025

(30) Foreign Application Priority Data
Nov. 10, 2022 (JP) 2022-180481

(51) Int. Cl. H10F 19/90

(52) U.S. Cl. CPC H10F 19/904

(57) ABSTRACT

The present invention provides a solar cell and a solar cell module capable of reducing the number of components and improving a yield as compared with the related art. A solar cell includes a first power generation region, a second power generation region, a first current collecting wiring portion configured to be electrically conducted to the first power generation region, a second current collecting wiring portion configured to be electrically conducted to the second power generation region, and a penetration part. The first current collecting wiring portion is provided independently of and not continuously to the second current collecting wiring portion, and is disposed at an interval from the second current collecting wiring portion with the penetration part interposed therebetween, and the penetration part includes one or a plurality of through holes, and extends in an extending direction of the first current collecting wiring portion to partition off the first power generation region and the second power generation region, and limits conduction between the first power generation region and the second power generation region.

### TECHNICAL FIELD

The present invention relates to a solar cell and a solar cell module.

### BACKGROUND ART

In recent years, a see-through solar cell module that is used as a window glass and transmits light in a thickness direction has been known (for example, Patent Document 1).

For example, in the see-through solar cell module of Patent Document 1, a plurality of solar cells divided into strips are arranged at intervals in a checkerboard shape, and the solar cells adjacent in an up-down direction are connected by an interconnector. By doing this, light can be transmitted in the thickness direction from a gap between the solar cells in a left-right direction.

### PRIOR ART DOCUMENTS

### Patent Documents

Patent Document 1: WO 2020/189240 A

### DISCLOSURE OF INVENTION

### Technical Problem

Incidentally, in the solar cell module of Patent Document 1, since a solar cell panel in-process is cut into small pieces and the solar cells are connected by the interconnector, a step of cutting the solar cell becomes complicated, and there is a problem that a yield is low and cost is high.

In addition, in the solar cell module of Patent Document 1, since each solar cell is small and the number of solar cells is large, positional displacement may occur in the solar cell at the time of encapsulation. Thus, it is necessary to contrive alignment of the solar cells.

As described above, the solar cell module of Patent Document 1 has room for further improvement.

Therefore, an object of the present invention is to provide a solar cell and a solar cell module capable of reducing the number of components and improving a yield as compared with the related art.

### Solution to Problem

One aspect of the present invention for solving the above-described problems is a solar cell including a first power generation region, a second power generation region, a first current collecting wiring portion configured to be electrically conducted to the first power generation region, a second current collecting wiring portion configured to be electrically conducted to the second power generation region, and a penetration part. The first current collecting wiring portion is provided independently of and not continuously to the second current collecting wiring portion, and is disposed at an interval from the second current collecting wiring portion with the penetration part interposed therebetween; and the penetration part includes one or a plurality of through holes, and extends in an extending direction of the first current collecting wiring portion to partition off the first power generation region and the second power generation region, and limits conduction between the first power generation region and the second power generation region.

According to this aspect, since the penetration part partitions off the first power generation region and the second power generation region and small pieces of the solar cell are formed in a pseudo manner in one solar cell, the number of components can be reduced, the yield can be improved as compared with the case of cutting the solar cell panel in-process as in Patent Document 1, and the cost can be reduced.

According to this aspect, since light can be transmitted in the thickness direction by the penetration part, it can be suitably used for a see-through solar cell module.

In a preferred aspect, an opening ratio by the penetration part is 10% or more and 90% or less.

In a preferred aspect, the first current collecting wiring portion and the second current collecting wiring portion each have a plurality of finger electrode parts extending in an extending direction of the penetration part, and a busbar electrode part connecting one end sides of the plurality of finger electrode parts, and a part of the penetration part is positioned between the busbar electrode part of the first current collecting wiring portion and the busbar electrode part of the second current collecting wiring portion.

According to this aspect, the penetration part is formed up to a portion between the busbar electrode parts closer to the end portion, and the opening ratio can be increased and the conduction between the first power generation region and the second power generation region can be limited.

Incidentally, since the see-through solar cell module of Patent Document 1 generates power by the entire solar cell, in a case where any one of solar cells constituting a solar cell string becomes unable to generate power due to a hot spot or the like, the entire string to which the solar cell belongs becomes unable to generate power. In the case of Patent Document 1, since each solar cell is extremely small, even though one row of solar cell strings cannot generate power, a decrease in a power generation area is small.

However, in the case of a normal solar cell module, since the solar cell has a certain size, when one solar cell cannot generate power, the power generation area of the solar cell module greatly decreases.

Therefore, one aspect of the present invention is a solar cell module including a plurality of the solar cells connected in series directly or via a conductive member. The plurality of solar cells includes a first solar cell and a second solar cell. In the first solar cell, the first current collecting wiring portion is connected to the first current collecting wiring portion of the second solar cell, and the second current collecting wiring portion is connected to the second current collecting wiring portion of the second solar cell.

According to this aspect, since the first power generation region of the first solar cell and the first power generation region of the second solar cell, and the second power generation region of the first solar cell and the second power generation region of the second solar cell can be substantially independently electrically connected respectively, even though the first power generation region of the first solar cell is short-circuited and cannot generate power, power can be generated on the second power generation region side of the first solar cell. Thus, the decrease in the power generation area can be suppressed as compared with the case of generating power by using the entire solar cell.

In addition, one aspect of the present invention is a solar cell module including a plurality of the solar cells, and includes a plurality of solar cell groups in which the solar cells are connected in series directly or via a conductive member. The solar cell group has a most upstream solar cell and a most downstream solar cell in a flow direction of electricity, in which the first current collecting wiring portion is connected to the first current collecting wiring portion of an adjacent solar cell of another solar cell group, and the second current collecting wiring portion is connected to the second current collecting wiring portion of the adjacent solar cell, respectively.

According to this aspect, in the solar cells between the most upstream solar cell and the most downstream solar cell in the flow direction of the electricity, the first power generation regions and the second power generation regions of the adjacent solar cells can be electrically connected individually. Thus, even though the first power generation region is short-circuited in a solar cell and cannot generate power, power can be generated on the second power generation region side, and the decrease in the power generation area can be suppressed as compared with the case of generating power by using the entire solar battery cell.

Meanwhile, in the see-through solar cell module of Patent Document 1, since the interval between adjacent solar cells is wider than the gap between the finger electrode parts in the solar cell, when a colored metal layer is used for the finger electrode parts, light is reflected by each finger electrode part in the solar cell, and light is not reflected by the gap between the solar cells. Thus, the gaps between the solar cells are conspicuous, the solar cell module cannot be uniformly viewed, and a sense of discomfort may be given in a case where the solar cell module is used as the window glass.

One aspect of the present invention is a solar cell module including a plurality of the solar cells. The solar cells are connected directly or via a conductive member, the solar cells include a first solar cell and a second solar cell, the first solar cell has a first side, the first current collecting wiring portion extends along the first side, and the second current collecting wiring portion extends in an extending direction of the first current collecting wiring portion at an interval from the first current collecting wiring portion, in the first solar cell, the penetration part is positioned between the first current collecting wiring portion and the second current collecting wiring portion, and extends in the extending direction of the first current collecting wiring portion, and the second solar cell includes a second side extending substantially parallel to the first side of the first solar cell, and a third current collecting wiring portion extending along the second side, and is disposed at an interval from the first solar cell, an interval between the first current collecting wiring portion and the second current collecting wiring portion is 0.9 times or more and 1.1 times or less an interval between the first current collecting wiring portion and the third current collecting wiring portion, and a distance between the first side of the first solar cell and the second side of the second solar cell is 0.9 times or more and 1.1 times or less a width of the penetration part.

The term “substantially parallel” as used herein refers to a case where the first side and the second side are substantially parallel, and refers to a case where an inclination angle of one side with respect to the other side is less than 3 degrees. That is, the “second side extending substantially parallel to the first side” refers to a second side having an inclination angle of less than 3 degrees with respect to the first side, and includes a case where the second side is parallel to the first side.

According to this aspect, since the interval between the first current collecting wiring portion and the second current collecting wiring portion in the first solar cell and the interval between the first current collecting wiring portion of the first solar cell and the third current collecting wiring portion of the second solar cell are substantially equal, and the interval between the gaps between the first solar cell and the second solar cell is substantially equal to the width of the penetration part constituted by the through hole, light can be uniformly transmitted. As a result, the appearance of the entire solar cell module appears substantially uniform, and a sense of discomfort is less likely to be given when the solar cell module is used as the window glass.

One aspect of the present invention is a solar cell module including a plurality of solar cells, the plurality of solar cells being connected to each other directly or via a conductive member. The plurality of solar cells each include a first power generation region, a second power generation region, a first current collecting wiring portion configured to be electrically connected to the first power generation region, a second current collecting wiring portion configured to be electrically connected to the second power generation region, and a conduction limiting part that partitions the first power generation region and the second power generation region, and limits conduction between the first power generation region and the second power generation region, the plurality of solar cells includes a first solar cell and a second solar cell, and in the first solar cell, the first current collecting wiring portion is, independently of the second current collecting wiring portion, connected to a first current collecting wiring portion of the second solar cell, and the second current collecting wiring portion is connected to a second current collecting wiring portion of the second solar cell.

According to this aspect, since the solar cell includes the conduction limiting part that partitions off the first power generation region and the second power generation region in the solar cell to limit conduction, the first power generation region and the second power generation region can substantially independently generate power. Thus, as compared with the case of cutting the solar cell panel in-process as in Patent Document 1, the number of components can be reduced, the yield can be improved, and the cost can be reduced.

According to this aspect, since the first power generation region of the first solar cell and the first power generation region of the second solar cell and the second power generation region of the first solar cell and the second power generation region of the second solar cell can be conducted substantially independently of each other, even though the first power generation region of the first solar cell cannot generate power due to a hot spot or the like, power can be generated on the second power generation region side of the first solar cell. Thus, the decrease in the power generation area can be suppressed as compared with the case of generating power by using the entire solar cell.

One aspect of the present invention is a solar cell module including a first solar cell, and a second solar cell. The first solar cell includes a first side, and includes a first current collecting wiring portion that extends along the first side, a second current collecting wiring portion that extends in an extending direction of the first current collecting wiring portion at an interval from the first current collecting wiring portion, and a penetration part that is positioned between the first current collecting wiring portion and the second current collecting wiring portion and has one or a plurality of through holes extending in the extending direction of the first current collecting wiring portion, the penetration part is a conduction limiting part that limits conduction between the first current collecting wiring portion side and the second current collecting wiring portion side in the first solar cell, the second solar cell is disposed at an interval from the first solar cell, the second solar cell includes a second side extending substantially parallel to the first side of the first solar cell, and a third current collecting wiring portion extending along the second side, an interval between the first current collecting wiring portion and the second current collecting wiring portion is 0.9 times or more and 1.1 times or less an interval between the first current collecting wiring portion and the third current collecting wiring portion, and a distance between the first side of the first solar cell and the second side of the second solar cell is 0.9 times or more and 1.1 times or less a width of the penetration part.

According to this aspect, since the interval between the first current collecting wiring portion and the second current collecting wiring portion in the first solar cell and the interval between the first current collecting wiring portion of the first solar cell and the third current collecting wiring portion of the second solar cell are substantially equal, and the interval between the gaps between the first solar cell and the second solar cell is substantially equal to the width of the conduction limiting part constituted by the through holes, light can be uniformly transmitted. As a result, the appearance of the entire solar cell module appears substantially uniform, and a sense of discomfort is less likely to be given when the solar cell module is used as the window glass.

According to this aspect, in the first solar cell, the first current collecting wiring portion side and the second current collecting wiring portion side can generate power substantially independently. Thus, as compared with the case of cutting the solar cell panel in-process as in Patent Document 1, the number of components can be reduced, the yield can be improved, and the cost can be reduced.

The above-described aspects can be mutually dependent, some configurations can be cited, or some configurations can be replaced between the aspects as long as the aspects are included in the technical scope of the present invention.

### Effect of Invention

According to the solar cell and the solar cell module of the present invention, it is possible to reduce the number of components and improving the yield as compared with the related art.

### BRIEF DESCRIPTION OF DRAWINGS

FIG. 1 is a perspective view of a solar cell module according to a first embodiment of the present invention.

FIG. 2 is a plan view of the solar cell module of FIG. 1, in which a first translucent substrate and a first sealing material are omitted for easy understanding.

FIGS. 3A and 3B are cross-sectional views of the solar cell module of FIG. 1, in which FIG. 3A is a cross-sectional view taken along line A-A of FIG. 2 and FIG. 3B is a cross-sectional view taken along line B-B of FIG. 2. In both of FIGS. 3A and 3B, hatching of a sealing member is omitted for easy understanding.

FIGS. 4A and 4B are explanatory views of the solar cell of FIG. 2, in which FIG. 4A is a perspective view as viewed from the first translucent substrate side and FIG. 4B is a perspective view as viewed from a second translucent substrate side by rotating the solar cell of FIG. 4A in a direction of an arrow C.

FIGS. 5A and 5B are explanatory views of a solar cell group of FIG. 2, in which FIG. 5A is a plan view illustrating a relationship between power generation regions of the solar cells and FIG. 5B is a plan view showing a relationship between collector electrodes of the solar cells.

FIG. 6 is a plan view illustrating a relationship between solar cells adjacent in a longitudinal direction in FIG. 2.

FIG. 7 is a perspective view of a solar cell according to another embodiment of the present invention.

FIG. 8 is a plan view of a solar cell module according to another embodiment of the present invention.

FIGS. 9A and 9B are explanatory views of a solar cell group according to another embodiment of the present invention, in which FIG. 9A is a plan view of the solar cell group in which through holes are arranged at positions of vertices of an equilateral triangle and FIG. 9B is a plan view of the solar cell group in which through holes are arranged at positions of vertices of a square.

### BEST MODE FOR CARRYING OUT THE INVENTION

Hereinafter, embodiments of the present invention will be described in detail.

A solar cell module 1 of a first embodiment of the present invention is suitably used mainly for applications as window glass, and is a see-through solar cell module capable of transmitting light in a thickness direction. In addition, the solar cell module 1 is a double-sided light receiving type solar cell module capable of converting light energy incident from both main surface sides into electric energy.

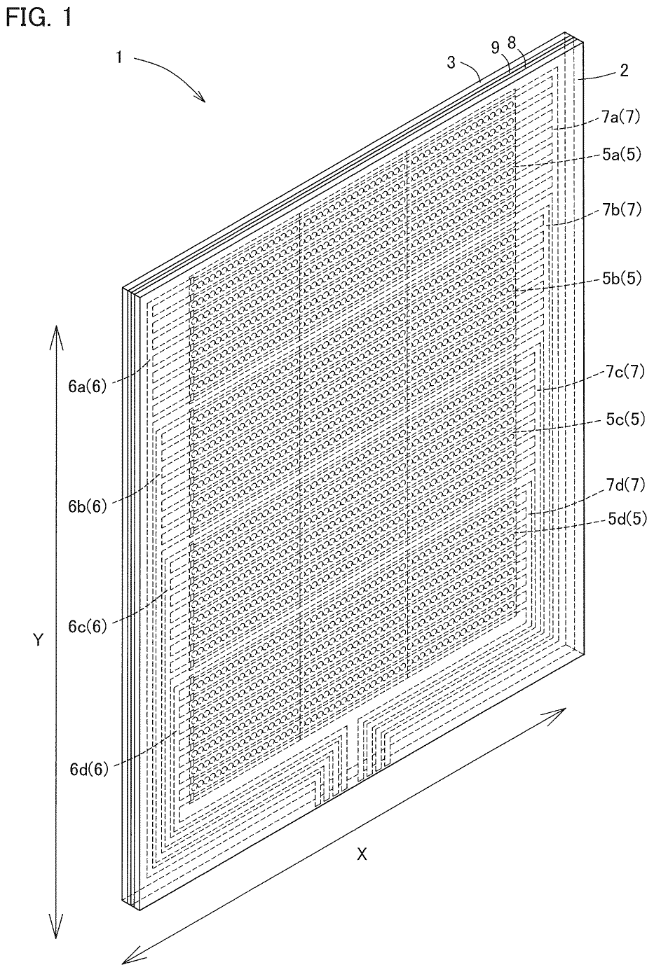

As illustrated in FIG. 1, the solar cell module 1 is mainly erected with respect to a horizontal plane, and is suitably attached to a window frame or the like in a vertical posture in which an up-down direction is a longitudinal direction Y and a left-right direction is a lateral direction X. Therefore, in the following description, unless otherwise specified, the posture of FIG. 1 is used as a reference.

As illustrated in FIG. 1, the solar cell module 1 includes translucent substrates 2 and 3, solar cell groups 5 (5a to 5d), first extraction wiring lines 6 (6a to 6d), second extraction wiring lines 7 (7a to 7d), a first sealing member 8, and a second sealing member 9.

In the solar cell module 1, the plurality of solar cell groups 5 and the extraction wiring lines 6 and 7 are disposed between two translucent substrates 2 and 3, and a gap between the translucent substrates 2 and 3 is filled with the sealing members 8 and 9 and are sealed.

### (Translucent Substrates 2 and 3)

The translucent substrates 2 and 3 are translucent members that spread in a planar shape and are capable of transmitting light in the thickness direction.

As illustrated in FIG. 1, the translucent substrates 2 and 3 of the present embodiment are quadrangular-shaped plate-like bodies extending in the lateral direction X and the longitudinal direction Y.

The translucent substrates 2 and 3 are members having translucency and insulating properties, and for example, a translucent insulation substrate such as a glass substrate can be used.

### (Solar Cell Group 5)

As illustrated in FIGS. 1 to 3, the solar cell groups 5 (5a to 5d) include a plurality of solar cells 20 and conductive adhesives 21, and are a series connection group in which the plurality of solar cells 20 are connected in series via the conductive adhesives 21.

### (Solar Cell 20)

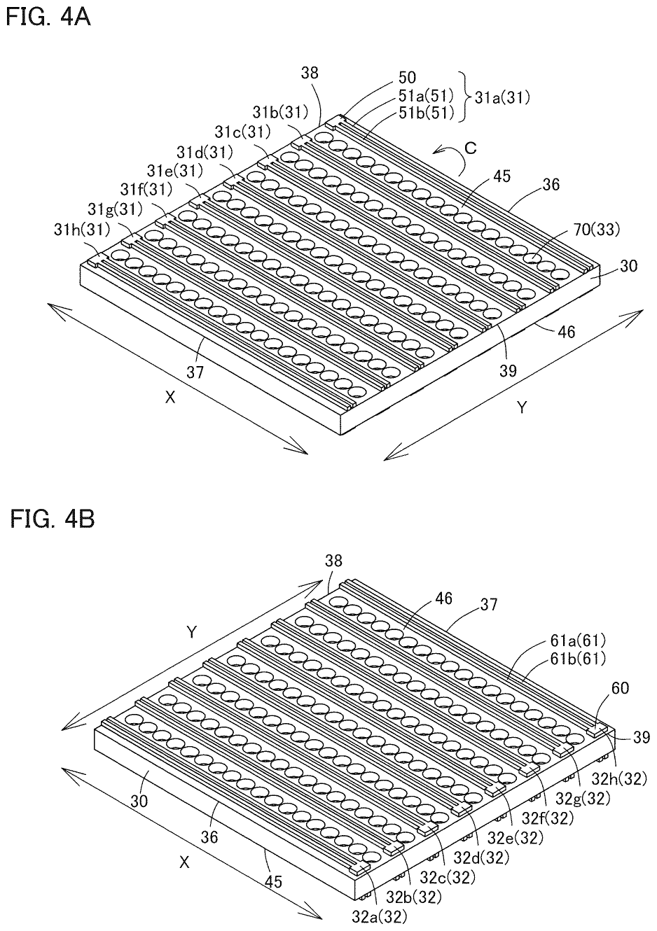

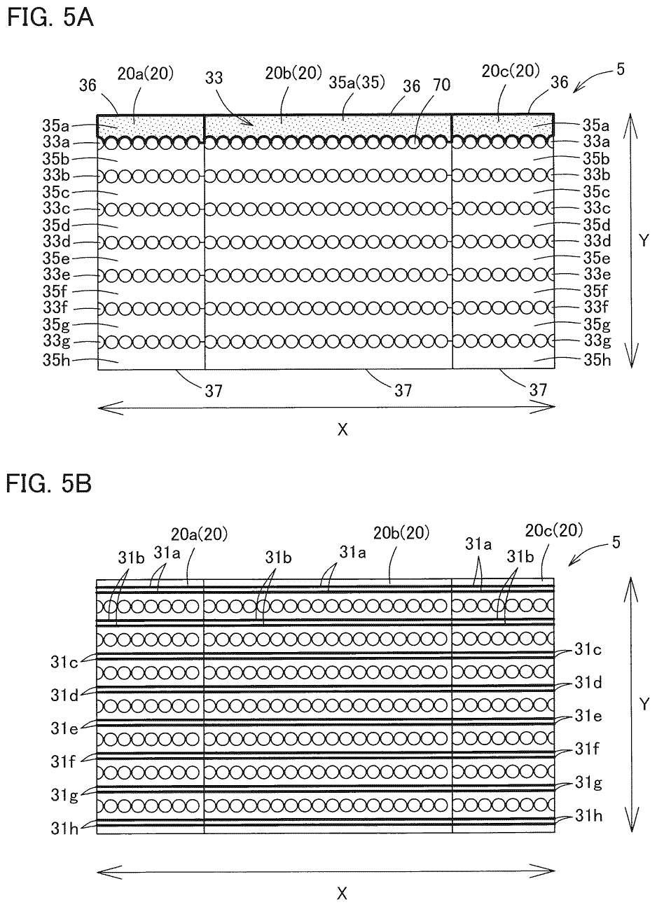

As illustrated in FIGS. 4 and 5, the solar cells 20 include photoelectric conversion substrates 30, first collector electrodes 31 (31 a to 31h), second collector electrodes 32 (32a to 32h), penetration parts 33 (33a to 33g), and power generation regions 35 (35a to 35h).

As illustrated in FIGS. 4A and 4B, the solar cell 20 has a quadrangular shape in plan view, and includes lateral sides 36 and 37 extending in the lateral direction X and longitudinal sides 38 and 39 extending in the longitudinal direction Y.

The solar cell 20 of the present embodiment has a square shape, the lateral sides 36 and 37 are parallel to each other, and the longitudinal sides 38 and 39 are parallel to each other.

As illustrated in FIGS. 4A and 4B, the photoelectric conversion substrate 30 is a plate-like substrate having both a first main surface 45 and a second main surface 46 as main surfaces, and is a portion that converts light energy into electric energy.

The photoelectric conversion substrate 30 is formed by stacking a semiconductor layer on a semiconductor substrate, and has a PN-junction between the semiconductor substrate and the semiconductor layer.

The solar cell 20 of the present embodiment is a crystalline solar cell using a crystalline silicon substrate as the semiconductor substrate.

As illustrated in FIG. 4A, the first collector electrode 31 is a conductive layer provided on the first main surface 45 side and partially stacked on the photoelectric conversion substrate 30. The first collector electrode 31 includes a first busbar electrode part 50 and a plurality of first finger electrode parts 51 (51a and 51b).

The first collector electrode 31 is not particularly limited as long as the first collector electrode has conductivity, and can be made of, for example, a metal such as gold, silver, aluminum, copper, or palladium, or a metal alloy thereof.

As illustrated in FIG. 4A, the first collector electrodes 31a to 31h are provided independently and individually, and are not directly connected to each other.

The first busbar electrode parts 50 are connection parts that are provided on one end (end portion on the longitudinal side 38 side) side in the lateral direction X in plan view to connect end portions of the first finger electrode parts 51a and 51b, and extend in the longitudinal direction Y. The first busbar electrode part 50 is a portion that functions as a land to which a second busbar electrode part 60 of the adjacent solar cell 20 is connected via the conductive adhesive 21. A width (length in the longitudinal direction Y) of the first busbar electrode part 50 is not particularly limited, but is preferably 1 mm or more and 8 mm or less.

The first finger electrode parts 51a and 51b are linear electrode parts extending in parallel to the lateral sides 36 and 37 from a middle section of the first busbar electrode part 50 in the longitudinal direction Y toward the other end portion (end portion on the longitudinal side 39 side) side in the lateral direction X.

The first finger electrode parts 51a and 51b are arranged side by side at an interval in the longitudinal direction Y, and both the first finger electrode parts extend from the first busbar electrode part 50 in the vicinity of one end portion (end portion on the longitudinal side 38 side) in the lateral direction X to the vicinity of the other end portion (end portion on the longitudinal side 39 side). That is, the first finger electrode parts 51a and 51b extend so as to cross the photoelectric conversion substrate 30 in the lateral direction X in plan view.

A width of each of the first finger electrode parts 51a and 51b is narrower than the width of the first busbar electrode part 50, and is preferably 30 μm or more and 70 μm or less.

As illustrated in FIG. 4B, the second collector electrode 32 is a conductive layer provided on the second main surface 46 side and partially stacked on the photoelectric conversion substrate 30.

The second collector electrode 32 includes the second busbar electrode part 60 and a plurality of second finger electrode parts 61 (61a and 61b).

The second collector electrode 32 is not particularly limited as long as the second collector electrode has conductivity, and can be made of, for example, a metal such as gold, silver, aluminum, copper, or palladium, or a metal alloy thereof.

The second collector electrodes 32a to 32h are independently and individually provided, and are not directly connected to each other.

The second busbar electrode parts 60 are connection parts that are provided on the other end portion (end portion on the longitudinal side 39 side) side in the lateral direction X to connect end portions of the second finger electrode parts 61a and 61b, and extend in the longitudinal direction Y.

The second busbar electrode part 60 is a portion that functions as a land to which the first busbar electrode part 50 of the adjacent solar cell 20 is connected via the conductive adhesive 21. A width (length in the longitudinal direction Y) of the second busbar electrode part 60 is not particularly limited, but is preferably 1 mm or more and 8 mm or less.

The second finger electrode parts 61a and 61b are linear electrode parts extending in parallel to the lateral sides 36 and 37 from a middle section of the second busbar electrode part 60 in the longitudinal direction Y toward one end (end portion on the longitudinal side 38 side) side in the lateral direction X. That is, the second finger electrode parts 61a and 61b extend in a direction opposite to the first finger electrode part 51a provided on the first main surface 45 side.

The second finger electrode parts 61a and 61b are arranged side by side at an interval in the longitudinal direction Y, and both the second finger electrode parts extend from the second busbar electrode part 60 in the vicinity of the other end portion (end portion on the longitudinal side 39 side) in the lateral direction X to the vicinity of the one end portion (end portion on the longitudinal side 38 side).

That is, the second finger electrode parts 61a and 61b extend so as to cross the photoelectric conversion substrate 30 in the lateral direction X, similarly to the first finger electrode parts 51a and 51b.

A width of each of the second finger electrode parts 61a and 61b is narrower than the width of the second busbar electrode part 60, and is preferably 30 μm or more and 70 μm or less.

As illustrated in FIGS. 5A and 5B, the penetration part 33 is a conduction limiting part (conduction limiting part) that extends in the lateral direction X, partitions off the power generation regions 35 and 35 adjacent in the longitudinal direction Y and limits conduction between the power generation regions 35 and 35.

The penetration part 33 is a portion that penetrates the photoelectric conversion substrate 30 in the thickness direction and allows light to pass in the thickness direction of the solar cell 20, and is a through hole group in which a plurality of through holes 70 are arranged in a row in the lateral direction X and arranged side by side at equal intervals.

An opening shape of the through hole 70 is not particularly limited, and may be a polygonal shape such as a triangle, a quadrangle, a pentagon, or a hexagon, or may be a circular shape, an oval shape, or a groove shape.

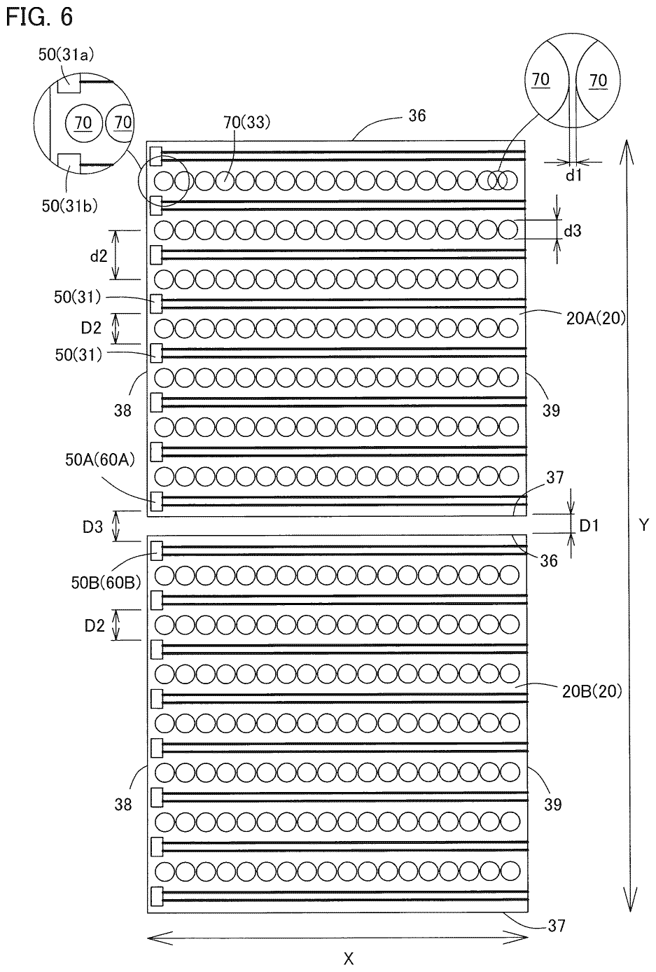

The opening shape of the through hole 70 of the present embodiment is a circular shape. In the penetration part 33, a shortest distance d1 between the through holes 70 and 70 adjacent in the lateral direction X illustrated in FIG. 6 is preferably 0.1 mm or more and 2 mm or less.

The penetration part 33 preferably has a portion where the power generation regions 35 and 35 adjacent in the longitudinal direction Y are connected between the through holes 70 and 70.

A diameter d3, which is a minimum inclusive circle diameter of the through hole 70 illustrated in FIG. 6, is preferably 0.1 mm or more and 2 mm or less.

The term “minimum inclusive circle diameter” as used herein refers to a smallest circle including all portions inside, and the minimum inclusive circle diameter of the through hole 70 refers to a smallest circle including the entire opening of the through hole 70 inside.

In the penetration part 33, an interval d2 between the through holes 70 and 70 adjacent to each other in the longitudinal direction Y is preferably an equal interval.

The solar cell 20 preferably has an opening ratio by the penetration part 33 of 10% or more and 90% or less.

The term “opening ratio” as used herein refers to a ratio of an area of an opening to an entire area in plan view.

The power generation region 35 is a power-generatable region that can generate power by receiving light, and is a region where the through hole 70 is not formed.

The power generation region 35 is a region divided by the penetration part 33 and arranged side by side in the longitudinal direction Y, and extends in the lateral direction X.

The power generation regions 35a and 35h positioned at both ends in the longitudinal direction Y illustrated in FIG. 5A are regions outside the penetration part 33 in the longitudinal direction Y, and the remaining power generation regions 35b to 35g are regions between the penetration parts 33 and 33 arranged side by side in the longitudinal direction Y.

As illustrated in FIGS. 5A and 5B, the power generation regions 35a to 35h are provided to correspond to the collector electrodes 31 and 32, and can be electrically connected to the collector electrodes 31 and 32.

### (Conductive Adhesive 21)

The conductive adhesive 21 is a conductive member having conductivity, and is an adhesive that connects the busbar electrode parts 50 and 60 of the solar cells 20 and 20 adjacent in the lateral direction X.

The conductive adhesive 21 of the present embodiment is a conductive adhesive film in which a conductive adhesive material is provided on both surfaces of a conductive film.

### (Extraction Wiring Lines 6 and 7)

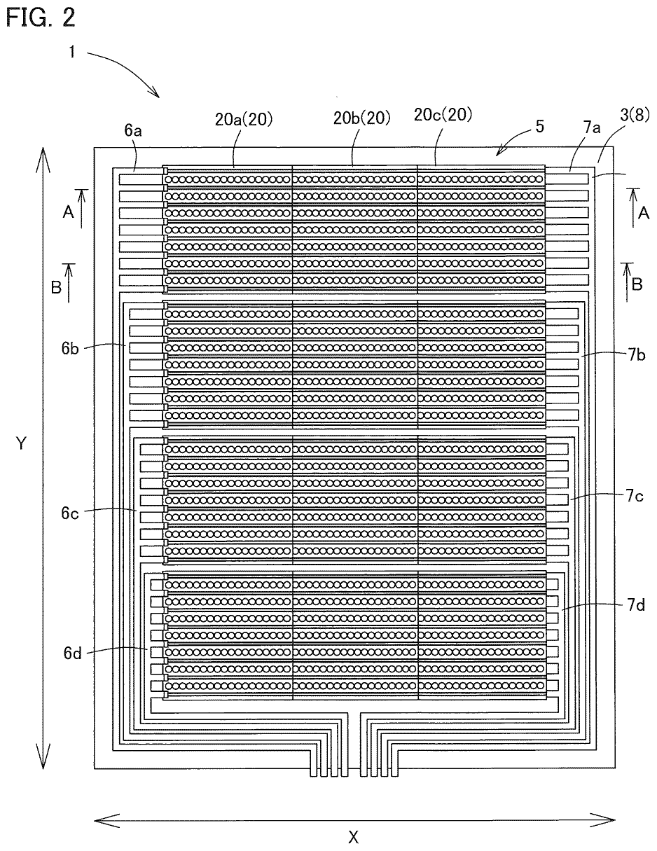

As illustrated in FIGS. 1 and 2, the extraction wiring lines 6 and 7 are wiring lines that extend from between the translucent substrates 2 and 3 to the inside and the outside and extract power generated from each solar cell group 5 to the outside.

The first extraction wiring line 6 has a comb shape, and can be bonded to each of the first busbar electrode parts 50 of the solar cell 20 directly or via a conductive adhesive.

That is, the first extraction wiring line 6 is connected to each of the first busbar electrode parts 50 of the solar cell 20, and thus, the first busbar electrode parts 50 can have the same potential.

The first extraction wiring lines 6a to 6d are independently provided, and are individually connected to a terminal box (not illustrated).

The second extraction wiring line 7 has a comb shape, and can be bonded to each of the second busbar electrode parts 60 of the solar cell 20 directly or via a conductive adhesive.

That is, the second extraction wiring line 7 is connected to each of the second busbar electrode parts 60 of the solar cells 20, and thus, the second busbar electrode parts 60 can have the same potential.

The second extraction wiring lines 7a to 7d are independently provided, and are individually connected to a terminal box (not illustrated).

### (Sealing Members 8 and 9)

The sealing members 8 and 9 are members having sealing properties and sealing the solar cell group 5 together with the translucent substrates 2 and 3, and are also adhesives for bonding the translucent substrates 2 and 3.

Next, a positional relationship between the portions of the solar cell module 1 of the present embodiment will be described.

In the solar cell module 1, as illustrated in FIGS. 1 and 2, the plurality of solar cell groups 5 are arranged side by side at intervals in the longitudinal direction Y (up-down direction), and a gap is formed between the solar cell groups 5 and 5 adjacent in the longitudinal direction Y.

In the solar cell module 1, an interval D1 between solar cells 20A and 20B of the solar cell groups 5 and 5 adjacent in the longitudinal direction Y illustrated in FIG. 6 (a shortest distance between the lateral sides 37 and 36) is preferably 0.9 times or more and 1.1 times or less a diameter d3 (a width of the penetration part 33), which is the minimum inclusive circle diameter of the through hole 70, and more preferably equal to the diameter d3.

In the solar cell module 1, the interval D2 between the busbar electrode parts 50 and 50 (60 and 60) adjacent in the longitudinal direction Y of the solar cells 20A and 20B illustrated in FIG. 6 is preferably 0.9 times or more and 1.1 times or less an interval D3 between the busbar electrode part 50A (60A) closest to the lateral side 37 in the solar cell 20A and the busbar electrode part 50B (60B) closest to the lateral side 36 in the solar cell 20B, and is more preferably equal to the interval D3.

In the solar cell module 1, the opening ratio by the penetration part 33 of each solar cell 20 and the gap between the solar cell groups 5 and 5 is preferably 10% or more and 90% or less.

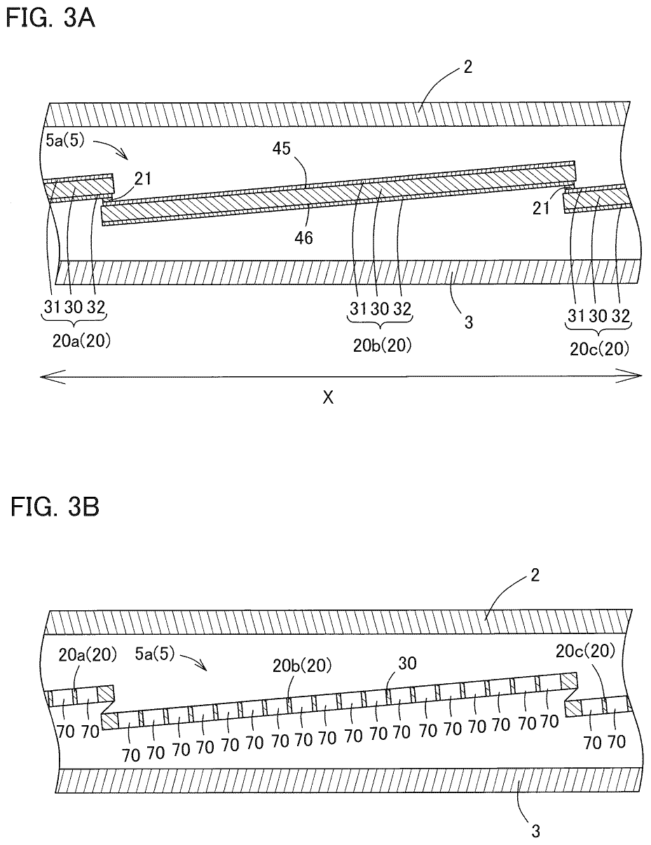

As illustrated in FIGS. 3A and 5B, in the solar cell 20a, each collector electrode 32 is connected to each collector electrode 31 of the adjacent solar cell 20b without being connected to another collector electrode 32 adjacent in the longitudinal direction Y, and in the solar cell 20b, each collector electrode 32 is connected to each collector electrode 31 of the adjacent solar cell 20c without being connected to another collector electrode 32 adjacent in the longitudinal direction Y.

As illustrated in FIG. 5A, the power generation regions 35a to 35h of the solar cell 20b are electrically connected to the power generation regions 35a to 35h of the solar cell 20a adjacent in the lateral direction X, and are electrically connected to the power generation regions 35a to 35h of the solar cell 20c.

That is, the power generation regions 35, 35, and 35 of the solar cells 20a to 20c constituting the solar cell group 5 are electrically connected in series to form power generation regions group, and these power generation region groups are electrically connected in parallel.

According to the solar cell module 1 of the first embodiment, the collector electrode 31a (first current collecting wiring portion) is not connected to the collector electrode 31b (second current collecting wiring portion) adjacent in the longitudinal direction Y, and is provided independently, and is disposed at an interval from the collector electrode 31b with the penetration part 33 interposed therebetween, and the penetration part 33 extends in an extending direction of the collector electrode 31a to partition off the first power generation region 35a and the second power generation region 35b, and limits conduction between the first power generation region 35a and the second power generation region 35b.

That is, the penetration part 33 physically partitions off the first power generation region 35a on the collector electrode 31a side and the second power generation region 35b on the collector electrode 31b side, and small pieces of the solar cells are formed in a pseudo manner in one solar cell 20. As a result, the number of components can be reduced as compared with the case of the related art, a yield can be improved, and the cost can be reduced. In addition, since the number of components can be reduced, it is easy to keep the interval between the solar cell groups 5 constant, and the penetration parts 33 and the gap between the solar cell groups 5 and 5 can be set to be similar appearance at a distance.

According to the solar cell module 1 of the first embodiment, since light can be transmitted in the thickness direction by the penetration part 33 of each solar cell 20 and the gap between the solar cells 20 and 20 adjacent in the longitudinal direction Y, the solar cell module 1 can function as the see-through solar cell module.

According to the solar cell module 1 of the first embodiment, as illustrated in FIG. 6, a part of the through hole 70 of the penetration part 33 is positioned between the busbar electrode part 50 (60) of the collector electrode 31a (first current collecting wiring portion) and the busbar electrode part 50 (60) of the collector electrode 31b (second current collecting wiring portion). Thus, the penetration part 33 can be provided up to the vicinity of the longitudinal sides 38 and 39 in the lateral direction X, and the conduction between the first power generation region 35a and the second power generation region 35b can be further limited.

According to the solar cell module 1 of the first embodiment, as illustrated in FIGS. 5A and 5B, in the first solar cell 20 b positioned between the solar cell 20 a on a most upstream side and the solar cell 20c on a most downstream side in a flow direction of electricity, the collector electrode 31a on the first main surface 45 side is connected to the collector electrode 32a on the second main surface 46 side of the second solar cell 20a without being connected to the collector electrode 31b adjacent in the longitudinal direction Y, and the collector electrode 31b on the first main surface 45 side is connected to the collector electrode 32b on the second main surface 46 side of the second solar cell 20a.

In addition, in the first solar cell 20b, the collector electrode 32a on the second main surface 46 side is connected to the collector electrode 31a on the first main surface 45 side of the third solar cell 20c without being connected to the collector electrode 32b adjacent in the longitudinal direction Y, and the collector electrode 32b on the second main surface 46 side is connected to the collector electrode 31b on the first main surface 45 side of the third solar cell 20c.

That is, the first power generation region 35a of the second solar cell 20a, the first power generation region 35a of the first solar cell 20b, and the first power generation region 35a of the third solar cell 20c are electrically connected in series, and the second power generation region 35b of the second solar cell 20a, the second power generation region 35b of the first solar cell 20b, and the second power generation region 35b of the third solar cell 20c are electrically connected in series.

Accordingly, according to the solar cell module 1 of the first embodiment, since the first power generation region 35a of each of the solar cells 20a to 20c and the second power generation region 35b of each of the solar cells 20a to 20c can be conducted substantially independently, even though the first power generation region 35a of the first solar cell 20b is short-circuited and cannot generate power, power can be generated on the second power generation region 35b side of the first solar cell 20b. Thus, a decrease in a power generation area can be suppressed as compared with a case where power is generated by using the entire solar cell 20.

According to the solar cell module 1 of the first embodiment, as illustrated in FIG. 6, the interval D2 between the collector electrode 31 (first current collecting wiring portion) and the collector electrode 31 (second current collecting wiring portion) adjacent in the longitudinal direction Y in the solar cell 20A (20B) is 0.9 times or more and 1.1 times or less the interval D3 between the collector electrode 31 (first current collecting wiring portion) closest to the lateral side 37 in the solar cell 20A and the collector electrode 31 (third current collecting wiring portion) closest to the lateral side 36 in the solar cell 20B.

In addition, according to the solar cell module 1 of the first embodiment, the lateral side 37 (first side) of the solar cell 20A and the lateral side 36 (second side) of the solar cell 20B are parallel in plan view, and the distance D1 between the lateral side 37 of the first solar cell 20A and the lateral side 36 of the second solar cell 20B is 0.9 times or more and 1.1 times or less a width d3 of the penetration part 33.

That is, in the solar cell module 1, since the interval between the collector electrodes 31 adjacent in the longitudinal direction Y is equal and the interval between the gaps between the solar cell 20A and the solar cell 20B is equal to the width of the penetration part 33 constituted by the through hole 70, light can be uniformly transmitted. As a result, the appearance of the entire solar cell module 1 appears substantially uniform, and a sense of discomfort is less likely to be given when the solar cell module 1 is used as a window glass.

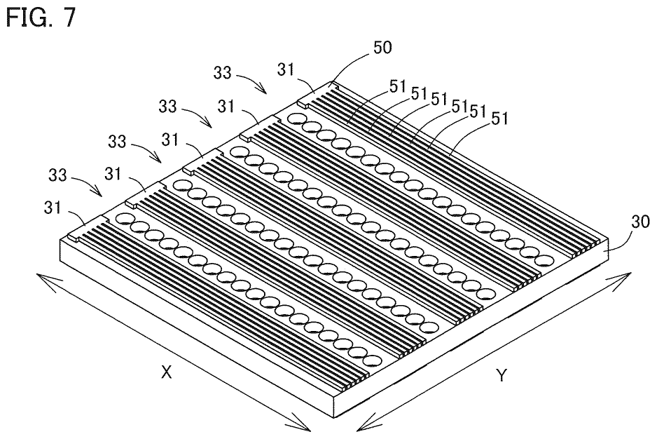

In the above embodiment, the first collector electrode 31 includes two first finger electrode parts 51a and 51b, but the present invention is not limited thereto. The number of first finger electrode parts 51 constituting the first collector electrode 31 is not particularly limited. The first collector electrode 31 may include three or more first finger electrode parts 51 as illustrated in FIG. 7. Similarly, the second collector electrode 32 includes two second finger electrode parts 61a and 61b, but the present invention is not limited thereto. The number of second finger electrode parts 61 constituting the second collector electrode 32 is not particularly limited. The second collector electrode 32 may include three or more second finger electrode parts 61.

In the above embodiment, seven penetration parts 33 partition off eight power generation regions 35, but the present invention is not limited thereto. One or more and six or less penetration parts 33 may partition off the power generation regions 35, or eight or more penetration parts 33 may partition off the power generation regions 35.

The opening ratio of the solar cell module 1 can be adjusted by changing the number of penetration parts 33 or changing the number of through holes 70 constituting the penetration parts 33 in this manner.

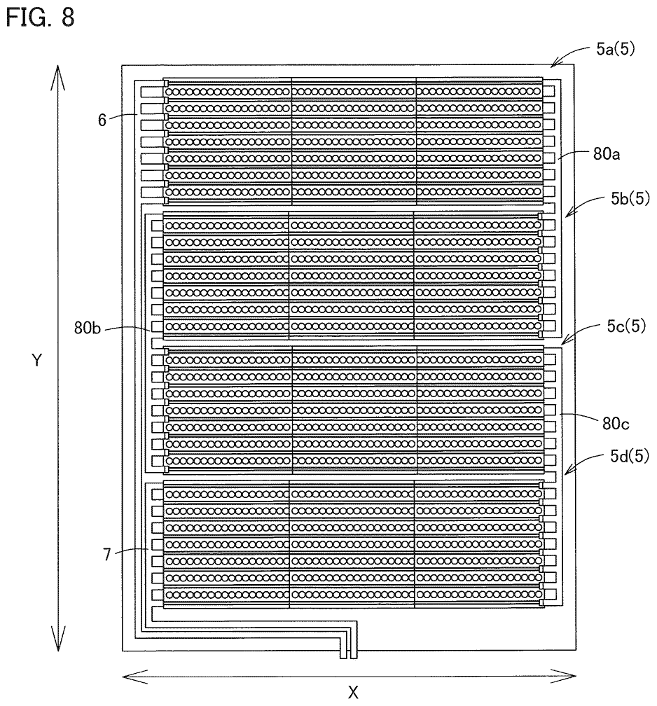

In the above embodiment, each of the solar cell groups 5a to 5d is connected in parallel to a terminal box (not illustrated) connected to an external load, but the present invention is not limited thereto. As illustrated in FIG. 8, the solar cell groups 5a to 5d may be connected by connection wiring lines 80a to 80c to form a series connection group, and the solar cell group 5a on the most upstream side and the solar cell group 5c on the downstream side of the series connection group may be connected to extraction wiring lines 6 and 7 to be connected in series to the terminal box. In this case, the solar cell groups 5 and 5 (for example, the solar cell groups 5a and 5b) adjacent in the longitudinal direction Y are disposed in a front-back reversed manner. That is, the solar cell groups 5 and 5 adjacent in the longitudinal direction Y have alternate positive and negative orientations.

In the above embodiment, the through holes 70 are arranged in a row in the penetration part 33, but the present invention is not limited thereto. The penetration part 33 may be formed by arranging the through holes 70 in a plurality of rows.

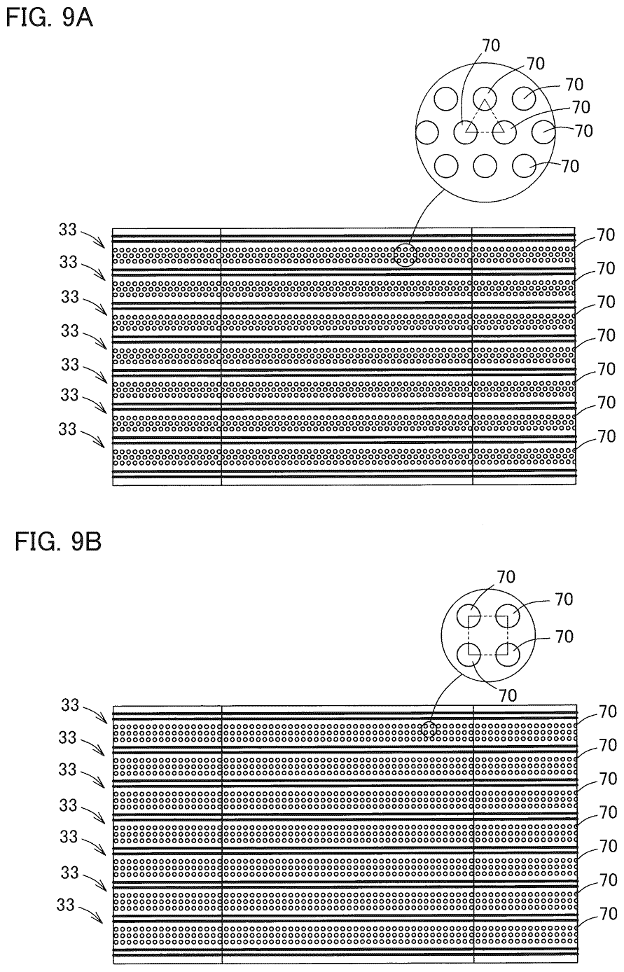

In this case, the through holes 70 and 70 adjacent in the longitudinal direction Y may be displaced in the lateral direction X as illustrated in FIG. 9A, or may be linearly arranged in the longitudinal direction Y as illustrated in FIG. 9B.

The penetration part 33 is preferably configured such that a figure formed by connecting centers of adjacent through holes 70 is plane-filled.

In the penetration part 33, the figure connecting centers of the most adjacent through holes 70 may have an equilateral triangular shape as illustrated in FIG. 9A, or a figure connecting the centers of the most adjacent through holes 70 may have a square shape as illustrated in FIG. 9B.

In the above embodiment, each solar cell group 5 is constituted by the three solar cells 20a to 20c, but the present invention is not limited thereto. As long as the number of solar cells 20 constituting any one of the solar cell groups 5 is 2 or more, the number of solar cells 20 constituting the other solar cell groups 5 is not particularly limited.

In the above embodiment, the solar cell module 1 is constituted by four solar cell groups 5a to 5d, but the present invention is not limited thereto. The solar cell module 1 may be constituted by one or more and three or less solar cell groups 5, or may be constituted by five or more solar cell groups 5.

In the above embodiment, the penetration part 33 is constituted by the plurality of through holes 70, but the present invention is not limited thereto. The penetration part 33 may be constituted by one through hole 70. In addition, in the solar cell 20, the adjacent power generation regions 35 and 35 may be partially connected, and an end portion in the extending direction of the penetration part 33 may be formed as a notch part. That is, the penetration part 33 may be a notch part partially extending in the lateral direction X from the end portions constituting the longitudinal sides 38 and 39.

In the above embodiment, the case where the solar cell 20 is the crystalline solar cell has been described, but the present invention is not limited thereto. The solar cell 20 may be another type of solar cell.

In the above embodiment, in the solar cell module 1, the solar cell groups 5 are arranged in the longitudinal direction Y (up-down direction), but the present invention is not limited thereto. The solar cell groups 5 may be arranged in the lateral direction X (left-right direction). In this case, the solar cell module 1 is preferably rotated by 90 degrees to be vertically and horizontally reversed.

In the above embodiment, the solar cells 20 and 20 belonging to the solar cell group 5 and adjacent in the lateral direction X are connected by the conductive adhesive 21, but the present invention is not limited thereto. These solar cells may be connected by other conductive members such as wiring lines.

In the above embodiment, each component member can be freely replaced or added between the embodiments without departing from the technical scope of the present invention.

### EXPLANATION OF REFERENCE SIGNS

1: solar cell module

20, 20 a to 20 c, 20A, 20B: solar cell (first solar cell and second solar cell)

21: conductive adhesive

31, 31a to 31h: first collector electrode (first current collecting wiring portion, second current collecting wiring portion, third current collecting wiring portion) 32, 32a to 32h: second collector electrode (first current collecting wiring portion, second current collecting wiring portion, third current collecting wiring portion)

33: penetration part (conduction limiting part)

35, 35a to 35h: power generation region (first power generation region, second power generation region)

36: lateral side (second side)

37: lateral side (first side)

50, 50A, 50B: first busbar electrode part

51, 51a, 51b: first finger electrode part

60, 60A, 60B: second busbar electrode part

61, 61a, 61b: second finger electrode part

70: through hole

1. A solar cell comprising:
a first power generation region;
a second power generation region;
a first current collecting wiring portion configured to be electrically conducted to the first power generation region;
a second current collecting wiring portion configured to be electrically conducted to the second power generation region; and
a penetration part,
wherein the first current collecting wiring portion is provided independently of and not continuously to the second current collecting wiring portion, and is disposed at an interval from the second current collecting wiring portion with the penetration part interposed therebetween, and
the penetration part includes one or a plurality of through holes, and extends in an extending direction of the first current collecting wiring portion to partition off the first power generation region and the second power generation region, and limits conduction between the first power generation region and the second power generation region.

2. The solar cell according to claim 1, wherein an opening ratio by the penetration part is 10% or more and 90% or less.

3. The solar cell according to claim 1,
wherein the first current collecting wiring portion and the second current collecting wiring portion each have a plurality of finger electrode parts extending in an extending direction of the penetration part, and a busbar electrode part connecting one end sides of the plurality of finger electrode parts, and
a part of the penetration part is positioned between the busbar electrode part of the first current collecting wiring portion and the busbar electrode part of the second current collecting wiring portion.

4. A solar cell module that includes a plurality of the solar cells according to claim 1, comprising
a solar cell group in which the plurality of solar cells are connected in series directly or via a conductive member,
wherein, the solar cell group has a most upstream solar cell and a most downstream solar cell in a flow direction of electricity, in which the first current collecting wiring portion is connected to the first current collecting wiring portion of an adjacent solar cell of another solar cell group, and the second current collecting wiring portion is connected to the second current collecting wiring portion of the adjacent solar cell, respectively.

5. A solar cell module comprising a plurality of the solar cells according to claim 1,
wherein the solar cells are connected directly or via a conductive member,
the solar cells include a first solar cell and a second solar cell,
the first solar cell has a first side, the first current collecting wiring portion extends along the first side, and the second current collecting wiring portion extends in an extending direction of the first current collecting wiring portion at an interval from the first current collecting wiring portion,
in the first solar cell, the penetration part is positioned between the first current collecting wiring portion and the second current collecting wiring portion, and extends in the extending direction of the first current collecting wiring portion, and
the second solar cell includes a second side extending substantially parallel to the first side of the first solar cell, and a third current collecting wiring portion extending along the second side, and is disposed at an interval from the first solar cell,
an interval between the first current collecting wiring portion and the second current collecting wiring portion is 0.9 times or more and 1.1 times or less an interval between the first current collecting wiring portion and the third current collecting wiring portion, and
a distance between the first side of the first solar cell and the second side of the second solar cell is 0.9 times or more and 1.1 times or less a width of the penetration part.

6. A solar cell module comprising
a plurality of solar cells, the plurality of solar cells being connected to each other directly or via a conductive member,
wherein the plurality of solar cells each include a first power generation region, a second power generation region, a first current collecting wiring portion configured to be electrically connected to the first power generation region, a second current collecting wiring portion configured to be electrically connected to the second power generation region, and a conduction limiting part that partitions the first power generation region and the second power generation region, and limits conduction between the first power generation region and the second power generation region,
the plurality of solar cells includes a first solar cell and a second solar cell, and
in the first solar cell, the first current collecting wiring portion is, independently of the second current collecting wiring portion, connected to a first current collecting wiring portion of the second solar cell, and the second current collecting wiring portion is connected to a second current collecting wiring portion of the second solar cell.

7. A solar cell module comprising:
a first solar cell; and
a second solar cell,
wherein the first solar cell includes a first side, and includes a first current collecting wiring portion that extends along the first side, a second current collecting wiring portion that extends in an extending direction of the first current collecting wiring portion at an interval from the first current collecting wiring portion, and a penetration part that is positioned between the first current collecting wiring portion and the second current collecting wiring portion and has one or a plurality of through holes extending in the extending direction of the first current collecting wiring portion,
the penetration part is a conduction limiting part that limits conduction between the first current collecting wiring portion side and the second current collecting wiring portion side in the first solar cell,
the second solar cell is disposed at an interval from the first solar cell,
the second solar cell includes a second side extending substantially parallel to the first side of the first solar cell, and a third current collecting wiring portion extending along the second side,
an interval between the first current collecting wiring portion and the second current collecting wiring portion is 0.9 times or more and 1.1 times or less an interval between the first current collecting wiring portion and the third current collecting wiring portion, and
a distance between the first side of the first solar cell and the second side of the second solar cell is 0.9 times or more and 1.1 times or less a width of the penetration part.

8. The solar cell according to claim 2,
wherein the first current collecting wiring portion and the second current collecting wiring portion each have a plurality of finger electrode parts extending in an extending direction of the penetration part, and a busbar electrode part connecting one end sides of the plurality of finger electrode parts, and
a part of the penetration part is positioned between the busbar electrode part of the first current collecting wiring portion and the busbar electrode part of the second current collecting wiring portion.

9. A solar cell module that includes a plurality of the solar cells according to claim 2, comprising
a solar cell group in which the plurality of solar cells are connected in series directly or via a conductive member,
wherein, the solar cell group has a most upstream solar cell and a most downstream solar cell in a flow direction of electricity, in which the first current collecting wiring portion is connected to the first current collecting wiring portion of an adjacent solar cell of another solar cell group, and the second current collecting wiring portion is connected to the second current collecting wiring portion of the adjacent solar cell, respectively.

10. A solar cell module comprising a plurality of the solar cells according to claim 2,
wherein the solar cells are connected directly or via a conductive member,
the solar cells include a first solar cell and a second solar cell,
the first solar cell has a first side, the first current collecting wiring portion extends along the first side, and the second current collecting wiring portion extends in an extending direction of the first current collecting wiring portion at an interval from the first current collecting wiring portion,
in the first solar cell, the penetration part is positioned between the first current collecting wiring portion and the second current collecting wiring portion, and extends in the extending direction of the first current collecting wiring portion, and
the second solar cell includes a second side extending substantially parallel to the first side of the first solar cell, and a third current collecting wiring portion extending along the second side, and is disposed at an interval from the first solar cell,
an interval between the first current collecting wiring portion and the second current collecting wiring portion is 0.9 times or more and 1.1 times or less an interval between the first current collecting wiring portion and the third current collecting wiring portion, and
a distance between the first side of the first solar cell and the second side of the second solar cell is 0.9 times or more and 1.1 times or less a width of the penetration part.
